(19) United States
(12) Patent Application Publication
(10) Pub. No.: US 2025/0016971 A1
(43) Pub. Date: Jan. 9, 2025

(54) JOB SWITCHING METHOD AND MOUNTING LINE

(71) Applicant: FUJI CORPORATION, Chiryu (JP)

(72) Inventor: Hideyuki YAMAGUCHI, Nagoya-shi (JP)

(73) Assignee: FUJI CORPORATION, Chiryu (JP)

(21) Appl. No.: 18/708,269

(22) PCT Filed: Dec. 6, 2021
(86) PCT No.: PCT/JP2021/044728

§ 371 Date: May 8, 2024

(51) Int. Cl. H05K 13/08

(52) U.S. Cl. CPC H05K 13/0857

(57) ABSTRACT

In a job switching method, when switching jobs, a first job switching is performed for a first mounting machine group from the most upstream mounting machine to a predetermined downstream mounting machine among multiple mounting machines constituting a mounting line, and a second job switching is performed for a second mounting machine group located downstream from the predetermined mounting machine. In the first job switching, jobs are switched so that production of a board of a second type is started after production of a board of a first type is completed in all the mounting machines in the first mounting machine group and a setup change is completed at least in a specific mounting machine in the first mounting machine group. Meanwhile, in the second job switching, jobs are switched so that the production of the board of the second type is started after a setup change is executed in an upstream mounting machine on which the production of the board of the first type is completed, in parallel with producing of the board of the first type by a downstream mounting machine in the second mounting machine group, and the setup change is completed.

### TECHNICAL FIELD

The present description discloses a job switching method and a mounting line.

### BACKGROUND ART

Conventionally, as this type of mounting line, there has been proposed a mounting line in which multiple mounting machines that mount components on a board are arranged, in which a setup change is performed in accordance with a continuous setup change production mode when production of a board of one type is completed and the type of board to be produced changes (for example, refer to Patent Literature 1). The continuous setup change production mode is a mode in which a setup change, transitioning from production of a board of a first type to production of a board of a second type, is performed in the upstream mounting machine, in parallel with producing of the board of the first type in the downstream mounting machine. The setup change is performed in order from the upstream mounting machine immediately after the completion of the production of the board of the first type, and as soon as the setup change is completed, the mounting of components on the board of the next second type is started. Therefore, in the mounting line, there is a timing at which the mounting of components for producing a board before the setup change, the setup change, and the mounting of components for producing a board after the setup change are performed in parallel.

### PATENT LITERATURE

Patent Literature 1: JP-A-2009-111087

### BRIEF SUMMARY

### Technical Problem

However, there may be instances where it is not possible to perform such a continuous setup change. For example, when specific combination components are mounted on separate mounting machines, it is not until a first component among the combination components is set on a first mounting machine that a second component to be set on a second mounting machine may be determined. Examples of combination components include an LED and a current limiting resistor for limiting a current applied to the LED. Not all LEDs can emit light with a uniform amount of light, and the amount of light emission varies depending on manufacturing factors or the like. Even in such a situation, in order to make the light amount of the illumination uniform, the resistance value of the current limiting resistor is changed according to the class of the LED. In this case, since the second component (current limiting resistor) is not determined and the second component cannot be set on a second mounting machine until a first component (LED), which is often mounted by the downstream mounting machine, among the combination components, is set on a first mounting machine, there are instances where the continuous setup change described above cannot be executed. Further, even when the first component (LED) is mounted by the mounting machine that is upstream of the second component (current limiting resistor), the production of the board is not guaranteed until the second component is actually set on the downstream mounting machine. If certainty is to be ensured, the production needs to be performed after both components of the combination components are determined. In this case, for all the mounting machines constituting the mounting line, when a setup change is performed after waiting for the production of the board of the first type to be completed and the setup change is completed, it is conceivable that the board of the second type is caused to flow to the most upstream mounting machine to start the production of the board of the second type, but a significant delay occurs in the production of the board of the second type.

A main object of the present disclosure is to switch jobs as efficiently as possible even when a continuous setup change cannot be performed in all mounting machines constituting a mounting line.

### Solution to Problem

The present disclosure employs the following means in order to achieve the main object described above.

The job switching method of the present disclosure is a job switching method in a mounting line in which multiple mounting machines configured to mount components on a board are arranged in a conveyance direction of the board, the method including: when switching from a job producing a board of a first type to a job producing a board of a second type, performing, for a first mounting machine group from a most upstream mounting machine to a predetermined downstream mounting machine among multiple mounting machines constituting the mounting line, first job switching of switching jobs so that production of the board of the second type is started after mounting of components on the board of the first type is completed in all mounting machines in the first mounting machine group and a setup change is completed at least in a specific mounting machine in the first mounting machine group, and performing, for a second mounting machine group located downstream of the predetermined mounting machine, second job switching of switching jobs so that the production of the board of the second type is started after a setup change is executed in an upstream mounting machine in the second mounting machine group on which the mounting of components on the board of the first type is completed, in parallel with the mounting of components on the board of the first type by a downstream mounting machine in the second mounting machine group, and the setup change is completed.

In the job switching method of the present disclosure, the first job switching is performed for the first mounting machine group from the most upstream mounting machine to the predetermined downstream mounting machine among the multiple mounting machines constituting the mounting line, and the second job switching is performed for the second mounting machine group located downstream from the predetermined mounting machine. In the first job switching, jobs are switched so that production of the board of the second type is started after the mounting of components on the board of the first type is completed in all the mounting machines in the first mounting machine group and the setup change is completed at least in a specific mounting machine in the first mounting machine group. Meanwhile, in the second job switching, jobs are switched so that the production of the board of the second type is started after a setup change is executed in an upstream mounting machine in the second mounting machine group on which the mounting of components on the board of the first type is completed, in parallel with the mounting of components on the board of the first type by a downstream mounting machine in the second mounting machine group, and the setup change is completed. Accordingly, even when the second job switching cannot be applied to all the mounting machines constituting the mounting line, it is possible to switch jobs more efficiently than when the first job switching is applied to all the mounting machines constituting the mounting line by applying the second job switching to some of the mounting machine.

In the production line of the present disclosure, the same effect as that of the job switching method of the present disclosure can be achieved by switching the jobs in the same manner as that of the job switching method of the present disclosure.

### BRIEF DESCRIPTION OF DRAWINGS

FIG. 1 is an external perspective view of a component mounting line.

FIG. 2 is a schematic configuration view of a component mounting machine.

FIG. 3 is a block diagram illustrating an electrical connection relationship of the component mounting line.

FIG. 4 is a diagram illustrating an example of feeder holding information.

FIG. 5 is a flowchart illustrating an example of switching mode setting processing.

FIG. 6 is a flowchart illustrating an example of job switching processing.

FIG. 7 is a flowchart illustrating an example of setup change support processing.

FIG. 8 is a diagram illustrating an example of combination component information.

FIGS. 9A to 9C are views illustrating a state of batch job switching.

FIGS. 10A to 10C are views illustrating a state of batch job switching.

FIGS. 11A to 11C are views illustrating a state of seamless job switching.

FIGS. 12A to 12C are views illustrating a state in which a component mounting machine that performs batch job switching and a component mounting machine that performs seamless job switching are determined.

### DESCRIPTION OF EMBODIMENTS

Next, an embodiment of the present disclosure will be described while referring to accompanying drawings.

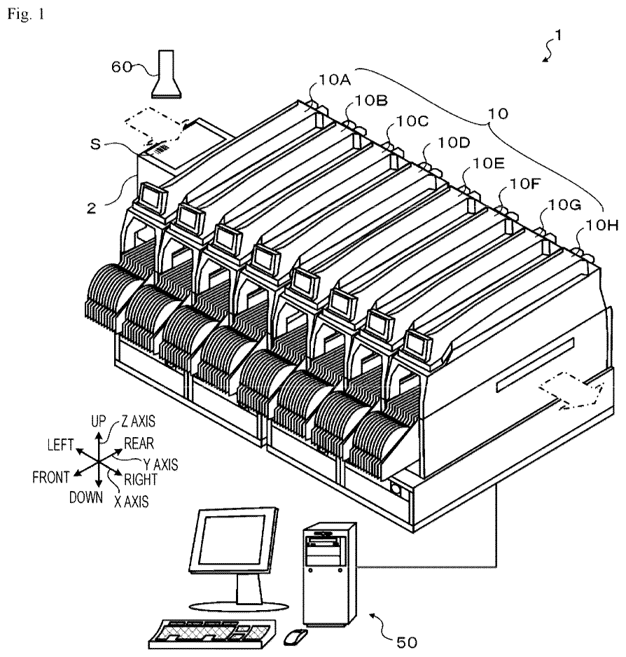

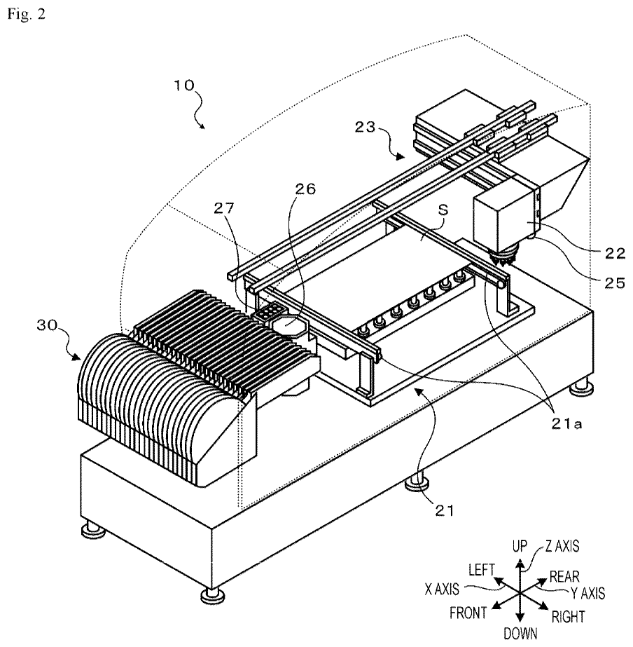

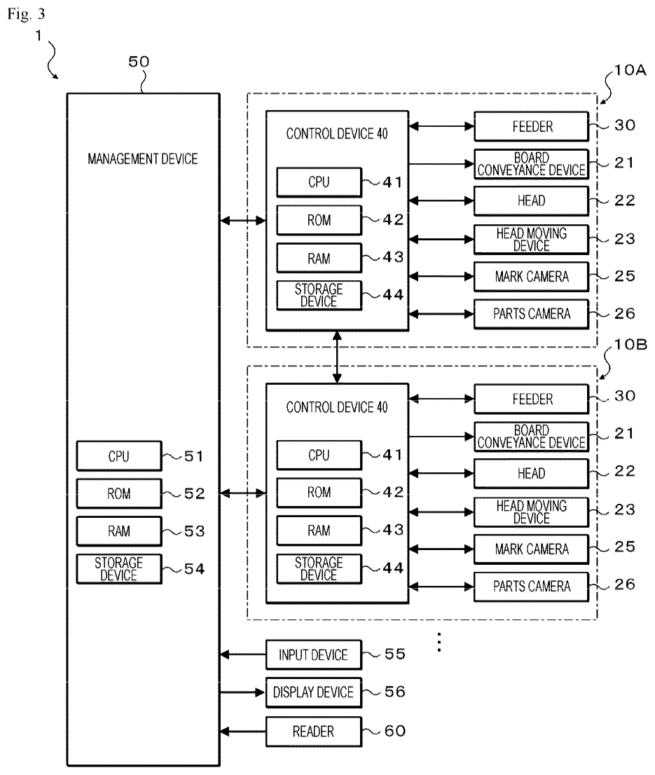

FIG. 1 is an external perspective view of component mounting line 1. FIG. 2 is a schematic configuration view of component mounting machine 10. FIG. 3 is a block diagram illustrating an electrical connection relationship of component mounting line 1. In FIG. 1 and FIG. 2, a left-right direction represents an X-axis direction, a front-rear direction represents a Y-axis direction, and an up-down direction represents a Z-axis direction.

Component mounting line 1 of the present embodiment produces board S on which components are mounted, and as illustrated in FIG. 1, includes multiple (eight) component mounting machines 10 (10A, 10B, 10C, 10D, 10E, 10F, 10G, and 10H) arranged along a conveyance direction of board S, and management device 50 that manages the entire line. In most upstream component mounting machine 10A in component mounting line 1, board supply device 2 for supplying board S to component mounting machine 10A is installed adjacent to the opposite side to downstream component mounting machine 10B. A board ID (for example, a barcode) for identifying the type of board S is attached to the surface of board S, and by reading the board ID with reader 60 (for example, a bar code reader), the type of board S to be produced is recognized by management device 50.

As illustrated in FIG. 2, each component mounting machine 10 includes feeder 30, board conveyance device 21, head 22, and head moving device 23.

Feeder 30 is detachably attached to a feeder base installed in a front part of component mounting machine 10. The feeder base is provided with multiple slots into which feeders 30 are respectively inserted, and feeders 30 are attached to the multiple slots and arranged in the X-axis direction. Feeder 30 is, for example, a tape feeder that includes a carrier tape in which components are respectively accommodated in multiple cavities formed at predetermined intervals, a reel around which the carrier tape is wound, and a tape feeding device that unwinds and feeds the carrier tape from the reel.

Board conveyance device 21 conveys in board S from board conveyance device 21 of upstream component mounting machine 10 and conveys out board S to board conveyance device 21 of downstream component mounting machine 10. As illustrated in FIG. 2, board conveyance device 21 is a belt conveyor device, and includes a pair of front and rear conveyor belts 21a each of which is wound around a pair of rollers and is disposed at a predetermined interval in the front-rear direction (Y-axis direction), and a belt drive device that circumferentially drives conveyor belts 21a. A first one of the pair of conveyor belts 21a is movable in a direction of approaching and separating from the second one. Board conveyance device 21 can convey multiple types of boards S having different sizes by adjusting the interval between the pair of conveyor belts 21a.

Head 22 includes a holder to which a suction nozzle (collecting member) is detachably attached, and a lifting and lowering device that lifts and lowers the holder. A negative pressure from a negative pressure source is supplied to the suction nozzle via a solenoid valve, and the suction nozzle can pick up (collect) components by the negative pressure.

Head moving device 23 moves head 22 in the front-rear and left-right directions (XY axis directions). Head moving device 23 includes a Y-axis slider that moves in the front-rear direction (in the Y-axis direction) by being driven by the Y-axis motor, and an X-axis slider that moves in the left-right direction (in the X-axis direction) with respect to the Y-axis slider by being driven by the X-axis motor. Head 22 is attached to the X-axis slider, and moves in the front-rear and left-right directions (XY axis directions) by being driven by the X-axis motor and the Y-axis motor.

Component mounting machine 10 also includes mark camera 25, parts camera 26, and nozzle stocker 27. Mark camera 25 captures an image of a reference mark attached to board S from above in order to detect the position of board S. Parts camera 26 captures an image of a component picked up by the suction nozzle from below in order to detect a pickup error or a pickup deviation. Nozzle stocker 27 stocks multiple types of suction nozzles attachable to the holder of head 22.

As illustrated in FIG. 3, control device 40 is configured as a microprocessor including CPU 41 as a main component, and includes ROM 42, RAM 43, storage device 44 (a hard disk drive, a solid state drive, or the like), and an input and output interface in addition to CPU 41. Control device 40 inputs a detection signal from a position sensor provided in head moving device 23 for detecting each position of head 22 in the X-axis direction and the Y-axis direction, and inputs an image signal captured by parts camera 26 or mark camera 25. Control device 40 outputs control signals to feeder 30, board conveyance device 21, head moving device 23, parts camera 26, mark camera 25, and the like.

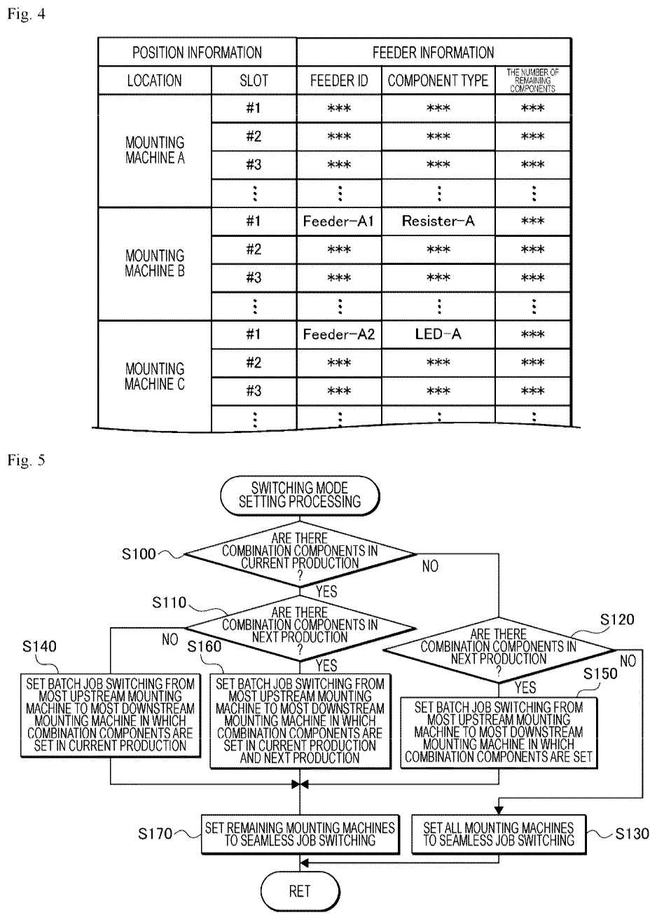

Management device 50 is a general-purpose computer including CPU 51, ROM 52, RAM 53, and storage device 54 (a hard disk drive, a solid state drive, or the like), and is communicably connected to control device 40 of each component mounting machine 10. Input device 55 such as a mouse and a keyboard, display device 56 that displays various information, and reader 60 are connected to management device 50. In addition to the production schedule, storage device 54 stores feeder holding information, job information, status information, and the like as various information required for production. These pieces of information are managed for each component mounting machine 10. Here, the production schedule is a schedule that specifies which components are mounted on which board S in which order in each component mounting machine 10, how many boards S (products) mounted in that manner are manufactured, and the like. The feeder holding information is information as to feeder 30 held by each component mounting machine 10. As illustrated in FIG. 4, the feeder holding information includes feeder information such as a feeder ID, a component type, and the number of remaining components, and position information such as a device (location) holding feeder 30 (component) and an attachment position (slot number) of feeder 30. The job information is information as to a production job to be executed in each component mounting machine 10. This job information includes a type of board to be produced, a type of component to be mounted, a mounting position for each component, a setting position (component set information) of a component (feeder 30) to be set in each component mounting machine 10, and the like. The component set information indicates a scheduled attachment position (scheduled slot) of feeder 30 accommodating the component, and is managed for each component mounting machine 10. The status information is information indicating the operation status of each component mounting machine 10. The status information includes during the production, during a setup change, during an abnormality occurrence, and the like.

Management device 50 is communicably connected to control device 40 of each component mounting machine 10 with each other by wire, and exchanges various information with each component mounting machine 10. Management device 50 receives the operation status from each component mounting machine 10 and updates the status information to the latest information. Management device 50 is communicably connected to feeder 30 attached to the feeder base of each component mounting machine 10 via control device 40. When feeder 30 is removed from component mounting machine 10 or is attached to component mounting machine 10, management device 50 receives an attachment or detachment status from corresponding component mounting machine 10 and updates the feeder holding information to the latest information.

Next, an operation of component mounting line 1 of the present embodiment configured as described above will be described. Control device 40 of each component mounting machine 10 receives a production job from management device 50, and performs a mounting process of mounting components on board S according to the received production job. That is, in the mounting process, CPU 41 first moves head 22 above the component supply position of feeder 30 using head moving device 23. Subsequently, CPU 41 lowers the suction nozzle using the lifting and lowering device to pick up the component by the suction nozzle. Next, CPU 41 moves the component picked up by the suction nozzle above parts camera 26 using head moving device 23, and captures an image of the component by parts camera 26. When capturing an image, CPU 41 processes the captured image of the components, measures the pickup deviation amount of the components, and corrects the component mounting position on board S. Then, CPU 41 moves the component picked up by the suction nozzle above the corrected mounting position using head moving device 23, and lowers the suction nozzle using the lifting and lowering device to mount the component on board S.

Next, an operation for changing the type of board S to be produced will be described. FIG. 5 is a flowchart illustrating an example of job switching mode setting processing executed by CPU 51 of management device 50. This processing is executed when the type of board S to be produced is changed. The change in the type of board S to be produced is recognized by management device 50 when the operator reads the board ID attached to board S to be produced next using reader 60.

In the job switching mode setting processing, CPU 51 of management device 50 first determines whether there are specific combination components among the components to be mounted in the current production (S100) and whether there are specific combination components among the components to be mounted in the next production (S110, S120). When it is determined that there is no specific combination component among the components to be mounted in both the current production and the next production (“NO” in S100 and “NO” in S120), CPU 51 sets the job switching mode to the seamless job switching mode in all component mounting machines 10 in component mounting line 1 (S130), and ends the job switching mode setting processing.

When it is determined that there are specific combination components among the components to be mounted in the current production but there is no specific combination component among the components to be mounted in the next production (“YES” in S100 and “NO” in S110), CPU 51 sets the job switching mode to the batch job switching mode, from most upstream component mounting machine 10 in component mounting line 1 to most downstream component mounting machine 10 among component mounting machines 10 in which the combination components are set in the current production (S140). Then, CPU 51 sets the job switching mode of remaining component mounting machines 10 in component mounting line 1 to the seamless job switching mode (S170), and ends the job switching mode setting processing.

When it is determined that there is no specific combination component among the components to be mounted in the current production but there are specific combination components among the components to be mounted in the next production (“NO” in S100 and “YES” in S120), CPU 51 sets the job switching mode to the batch job switching mode, from most upstream component mounting machine 10 in component mounting line 1 to most downstream component mounting machine 10 among component mounting machines 10 in which the combination components are set in the next production (S150). Then, CPU 51 sets the job switching mode in remaining component mounting machines 10 in component mounting line 1 to the seamless job switching mode (S170), and ends the job switching mode setting processing.

When it is determined that there are specific combination components among the components to be mounted in both the current production and the next production (“YES” in S100 and “YES” in S110), CPU 51 sets the job switching mode to the batch job switching mode, from most upstream component mounting machine 10 in component mounting line 1 to most downstream component mounting machine 10 among component mounting machines 10 in which the combination components are set in the current production and component mounting machines 10 in which the combination components are set in the next production (S160). Then, CPU 51 sets the job switching mode in remaining component mounting machines 10 in component mounting line 1 to the seamless job switching mode (S170), and ends the job switching mode setting processing.

As described above, in the present embodiment, when specific combination components are not included in the components to be mounted in both the current production and the next production, the job switching of all component mounting machines 10 in component mounting line 1 is performed by seamless job switching (second job switching). Conversely, when specific combination components are included in the components to be mounted in any one of the current production and the next production, the job switching of some of component mounting machines 10 including from most upstream component mounting machine 10 to component mounting machine 10 in which the combination components are set is performed in the batch job switching mode (first job switching), and the switching of the remaining jobs is performed in the seamless job switching mode (second job switching). The batch job switching mode (first job switching) is a mode in which the production of board S of the next production (second type) is not started until the mounting of components on board S of the current production (first type) is completed and the setup change is completed in all component mounting machines 10 in which the batch job switching mode is set. In addition, the seamless job switching mode (second job switching) is a mode in which, when upstream component mounting machine 10 among multiple component mounting machines 10 in which the seamless job switching mode is set completes the mounting of components on board S for the current production and conveys out board S to downstream component mounting machine 10, a setup change is performed, in parallel with the mounting of components on board S for the current production by downstream component mounting machine 10, and as soon as the setup change is completed, the production of board S for the next production is started.

Here, examples of specific combination components include an LED and a current limiting resistor for limiting a current applied to the LED. Not all LEDs can emit light with a uniform amount of light, and the amount of light emission varies depending on manufacturing factors or the like. Even in such a situation, in order to make the light amount of the illumination uniform, in the present embodiment, the resistance value of the current limiting resistor is changed according to the class of the LED. In this case, in the setup change, until feeder 30 accommodating a first component (LED) among the combination components is set on first component mounting machine 10, a second component (resistance value necessary for the current limiting resistor) is not determined, and feeder 30 accommodating the second component cannot be set on second component mounting machine 10. For this reason, when the specific combination components are set on separate component mounting machines 10, there may be instances where it is not possible to perform the setup change in order from the upstream side. For example, when the second component (current limiting resistor) is set on component mounting machine 10 that is upstream of the first component (LED), at least a part of work in the setup change of upstream component mounting machine 10 (setting of the second component) needs to be performed after the setup change (setting of the first component) of downstream component mounting machine 10, so that it is not possible to apply the seamless job switching mode that performs the setup change in order from the upstream for multiple component mounting machines 10 in which these combination components are set. Here, in the present embodiment, the job switching from most upstream component mounting machine 10A to component mounting machine 10 in which the specific combination components are set is collectively performed. However, when the job switching is performed in the batch job switching mode in all component mounting machines 10, the start of the next production is greatly delayed. For this reason, in the present embodiment, component mounting machines 10 that perform the batch job switching mode are limited to only necessary ones, and the job switching of remaining component mounting machines 10 are performed in the seamless job switching mode, thereby switching the jobs as efficiently as possible.

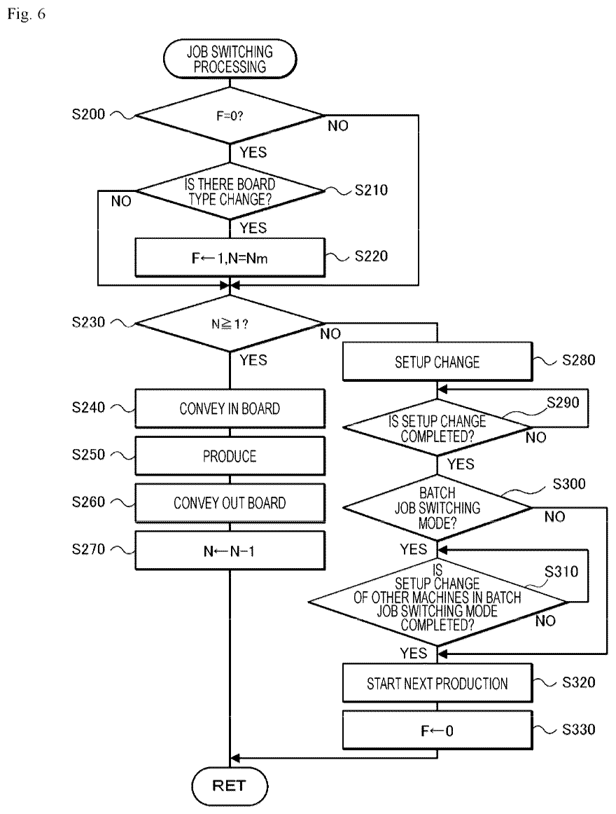

FIG. 6 is a flowchart illustrating an example of job switching processing executed by control device 40. This processing is executed for each component mounting machine 10.

When the job switching processing is executed, CPU 41 of control device 40 first determines whether flag F has a value of 0 (S200). When it is determined that the value of flag F is 0, it is determined whether the board type is changed from board S for the current production to board S for the next production (S210). This determination can be made based on the acquired information by acquiring information (board type change information) indicating that the board type is changed from management device 50 when the board ID attached to next production board S is read by reader 60. When it is determined that the board type is changed, CPU 41 sets flag F to the value 1 and sets the remaining board count value N to the number of remaining boards Nm upon board type change acquisition (S220). The number of remaining boards Nm upon board type change acquisition is the remaining number of boards S to be produced in the current production until the board type is changed. The number of remaining boards Nm upon board type change acquisition is different for each component mounting machine 10, and is set to a number obtained by subtracting 1 from the order number counted downstream from most upstream component mounting machine 10A. For example, in second component mounting machine 10B adjacent to the downstream of most upstream component mounting machine 10A, the number of remaining boards upon board type change acquisition is 1. When it is determined that flag F is not 0 but 1 in S200, flag F is already set to 1, and thus CPU 41 proceeds to S230.

Next, CPU 41 determines whether the remaining board count value N is equal to or greater than 1, that is, whether there are remaining boards S to be produced in the current production (S230). When it is determined that the remaining board count value N is equal to or greater than the value 1, CPU 41 conveys in board S from board supply device 2 or upstream component mounting machine 10 and mounts the components, and then conveys out board S to the downstream side (S240 to S260), decrements the remaining board count value N by the value 1 (S270), and ends the job switching processing. CPU 41 conveys in board S for the current production and mounts the components on conveyed board S until the remaining board count value N becomes less than 1, and repeats the processing of decrementing the remaining board count value N by 1.

When it is determined in S230 that the count value of remaining components is less than 1, CPU 41 performs a setup change (S280) and waits for the setup change to be completed (S290). The setup change includes work of adjusting the interval between the pair of conveyor belts 21a of board conveyance device 21 to be an interval corresponding to the width of next production board S, setting feeder 30 accommodating the component to be mounted on next production board S on the feeder base of corresponding component mounting machine 10, and setting the suction nozzle to be used in the next production on nozzle stocker 27.

When it is determined that the setup change is completed, CPU 41 determines whether the job switching mode set in its own machine (component mounting machine 10 executing the job switching processing) is the batch job switching mode (S300). This determination can be made by acquiring the job switching mode set by the switching mode setting processing from management device 50 through communication. When it is determined that the job switching mode set in its own machine is not the batch job switching mode but the seamless job switching mode, as soon as the setup change of the own machine is completed, CPU 41 conveys in board S to be produced next from the upstream side and starts production (S320), sets the value of flag F to 0 (S330), and ends the job switching processing. In the seamless job switching mode, in component mounting machine 10 (the second mounting machine group) in which the seamless job switching mode is set, after upstream component mounting machine 10 completes the mounting of components on board S for the current production and conveys out board S to downstream component mounting machine 10, a setup change is performed by upstream component mounting machine 10, in parallel with the mounting of components on board S for the current production by downstream component mounting machine 10, and as soon as the setup change is completed, board S for the next production is conveyed in and the production is started.

Conversely, when it is determined that the job switching mode is the batch job switching mode, CPU 41 waits for the setup change of other machines (component mounting machines 10 other than component mounting machine 10 executing the job switching processing) set in the batch job switching mode to be completed (S310). When it is determined that the setup change of other machines set in the batch job switching mode is completed, CPU 41 conveys in board S to be produced next from the upstream side and starts the production (S320), sets the value of flag F to 0 (S330), and ends the job switching processing. In the batch job switching mode, in all component mounting machines 10 (first mounting machine group) set in the batch job switching mode, the production of board S for the next production is not started until the mounting of components on board S for the current production is completed and the setup change is completed.

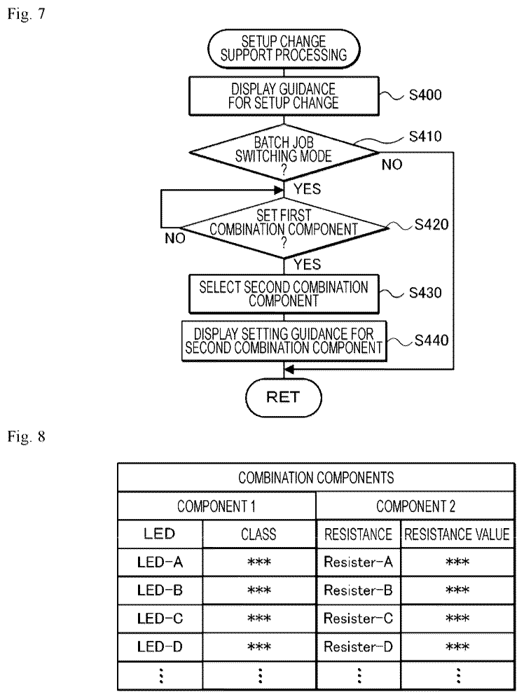

Next, a setup change support processing for guiding work to be performed by the operator in the setup change executed in S280 of the job switching processing will be described. Examples of work to be performed by the operator in the setup change include work of setting feeder 30 accommodating the component to be mounted on board S in the next production on the feeder base of component mounting machine 10 and work of setting the suction nozzle used for picking up the component in the next production on nozzle stocker 27. FIG. 7 is a flowchart illustrating an example of setup change support processing executed by management device 50. This processing is executed when a setup change occurs in any component mounting machine 10 in component mounting line 1.

When the setup change support processing is executed, CPU 51 of management device 50 first displays guidance for setup change on display device 56 (S400). The setup change guidance display includes information relating to component mounting machine 10 targeted for the setup change, information relating to the component to be set on component mounting machine 10, information relating to a position (slot number) where the component (feeder 30) is to be set, information relating to the suction nozzle to be set in nozzle stocker 27, and the like. Subsequently, CPU 51 determines whether the job switching mode of component mounting machine 10 targeted for the setup change is the batch job switching mode (S410). When it is determined that the job switching mode of component mounting machine 10 targeted for the setup change is the batch job switching mode, CPU 51 determines that specific combination components are included among the components to be set on component mounting machine 10 targeted for the setup change, and waits until a first combination component is set (S420). When it is determined that a first combination component is set, CPU 51 selects the type of the second combination component from the multiple components (S430). In the present embodiment, the first combination component is an LED, and a second combination component is a current limiting resistor. The processing of S430 is performed by selecting a current limiting resistor having a resistance value corresponding to the set LED from multiple current limiting resistors having different resistance values in order to make the light amount of the illumination uniform even when the lot or the like of the LED to be used is changed. Specifically, the selection of the current limiting resistor is performed in such a manner that the relationship between the LED class and the resistance value of the current limiting resistor is pre-determined and stored the relationship as a table, and when the LED is selected, the corresponding current limiting resistor is derived from the table. An example of this table is illustrated in FIG. 8. Then, CPU 51 displays, on display device 56, a guidance for guiding the setting of the second combination component (S440), and ends the setup change support processing.

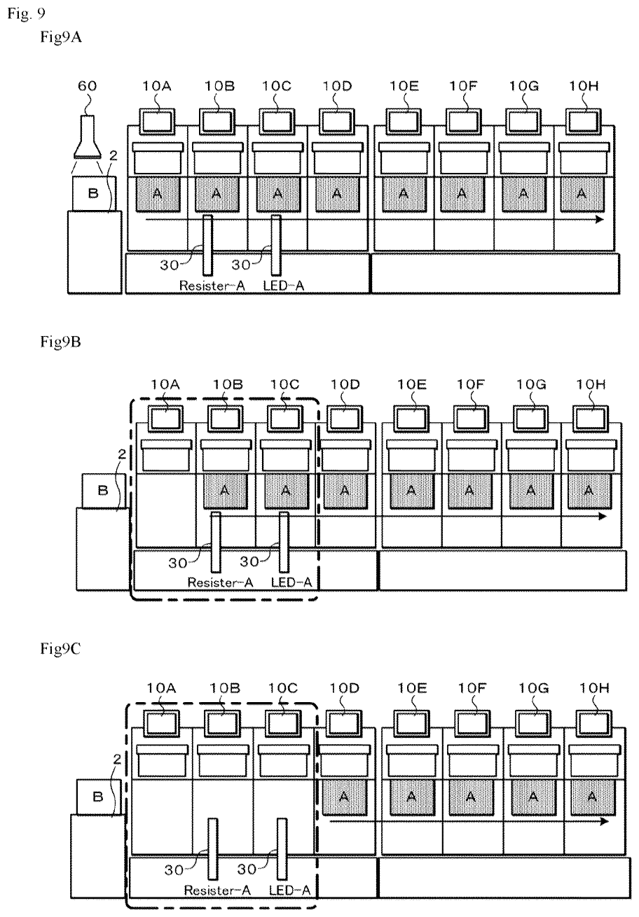

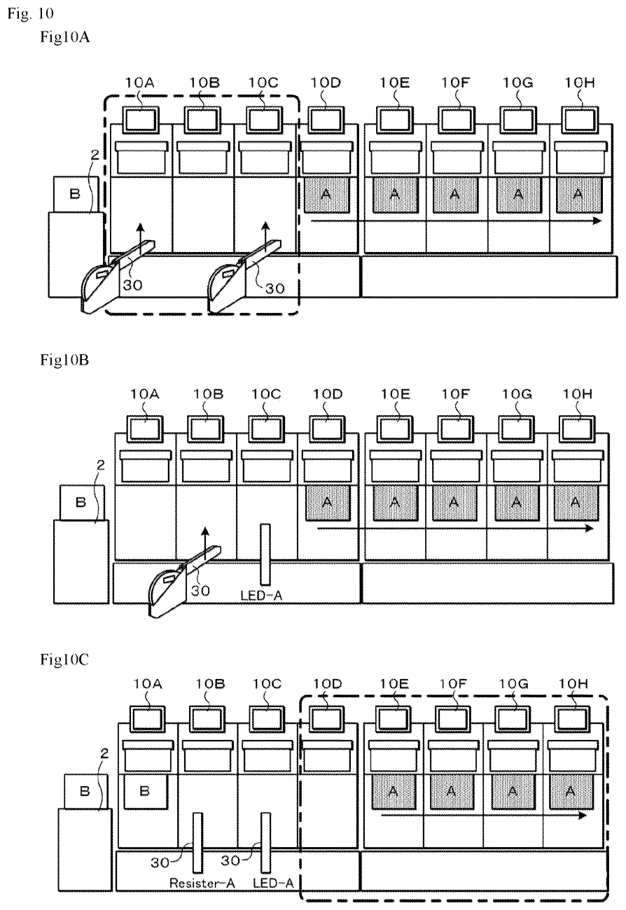

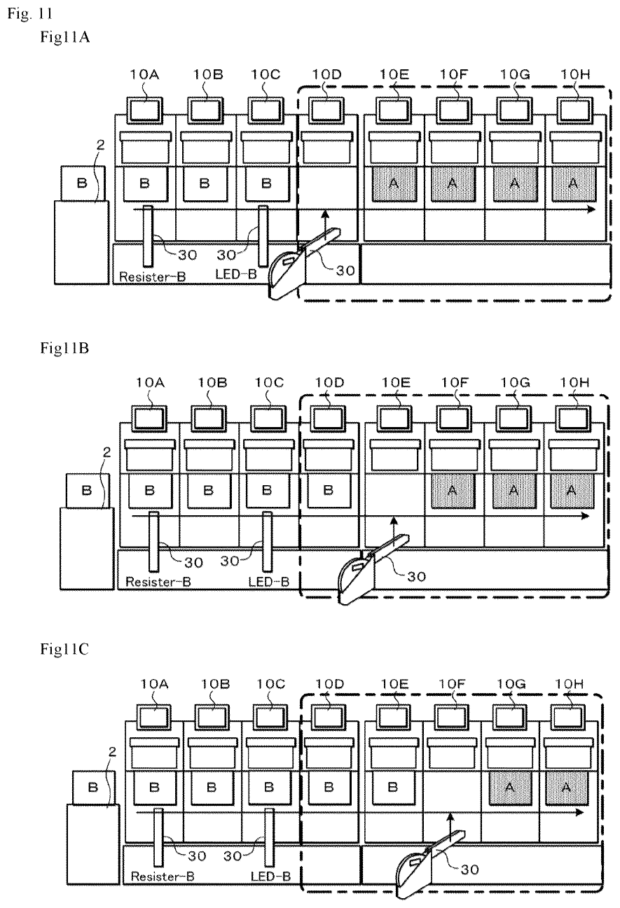

FIGS. 9A to 9C and FIGS. 10A to 10C are views illustrating a state of batch job switching. FIGS. 11A to 11C are views illustrating a state of seamless job switching. CPU 51 of management device 50 recognizes that the board type is changed by reading the board ID attached to the board of second type B using reader 60 during the production of the board of first type A (refer to FIG. 9A). When CPU 51 recognizes the change of the board type, CPU 51 sets the batch job switching mode from most upstream component mounting machine 10A to most downstream component mounting machine 10C among component mounting machines 10B and 10C in which specific combination components (LED-A and Resister-A) are set in the current production and component mounting machines 10B and 10C in which specific combination components are set in the next production (refer to the inside the chain line in FIGS. 9B and 9C). When the batch job switching mode is set in multiple component mounting machines 10A, 10B, and 10C, in all component mounting machines 10A, 10B, and 10C in which the batch job switching mode is set, the production of the board of second type B is not started until the mounting of components on last board S for the current production is completed and the setup change is completed. In the present embodiment, the setup change is performed by the operator, and the work by the operator is supported by the setup change support processing. That is, when the specific combination components are included in the components to be set on component mounting machine 10 in the setup change, CPU 51 first guides component mounting machine 10A in which the first combination component (LED) is to be set. Then, when the first combination component (LED-B) is set, CPU 51 selects the second combination component (Resister-B), and guides the selected second combination component and component mounting machine 10C on which this component is to be set. When the second combination component (feeder 30) is set on component mounting machine 10C and the setup change is completed in all component mounting machines 10A, 10B, and 10C in the batch job switching mode (refer to FIG. 10B), the board of second type B is conveyed in and the next production is started (refer to FIG. 10C).

In addition, CPU 51 sets component mounting machines 10D, 10E, 10F, 10G, and 10H, which are not set in the batch job switching mode, to the seamless job switching mode (refer to the inside the chain line in FIG. 10C). The setup change of component mounting machines 10D, 10E, 10F, 10G, and 10H in which the seamless job switching mode is set is performed immediately after the mounting of components on the last board of first type A is completed in order from upstream component mounting machine 10D. Then, as soon as the setup change is completed, the board of second type B is conveyed in and the next production is started (refer to FIGS. 11A to 11C). Accordingly, the mounting of components on the board of first type A before the setup change, the setup change, and the mounting of components on the board of second type B after the setup change are performed in parallel, so that the job switching can be performed efficiently and the production efficiency can be increased.

In the examples of FIGS. 9A to 9C, 10A to 10C, and 11A to 11C, when the second component (current limiting resistor) is set on component mounting machine 10 that is upstream of the first component (LED), the job switching mode from most upstream component mounting machine 10A to component mounting machine 10, in which the combination component (the first component) is set, is set in the batch job switching mode. Even when the second component (current limiting resistor) is set on component mounting machine 10 that is downstream of first component (LED), similarly, the job switching mode may be set to the batch job switching mode, from most upstream component mounting machine 10A to component mounting machine 10 in which the combination component (the second component) is set. In the latter case, since the setting destination of the first component (LED) set first is upstream component mounting machine 10 and the setting destination of the second component (current limiting resistor) set later is downstream component mounting machine 10, the setup change can be performed in order from the upstream side. However, since the production of board S is not guaranteed until the second component is actually set on downstream component mounting machine 10, the production needs to be performed after both components of the combination components are determined in order to ensure the certainty. Even in the latter case, the reason why the batch job switching mode is applied to the multiple component mounting machines 10 in which the combination components are set is based on this. However, when the second component (current limiting resistor) is set on component mounting machine 10 that is downstream of the first component (LED), the job switching mode of all component mounting machines 10 in component mounting line 1 may be set to the seamless job switching mode.

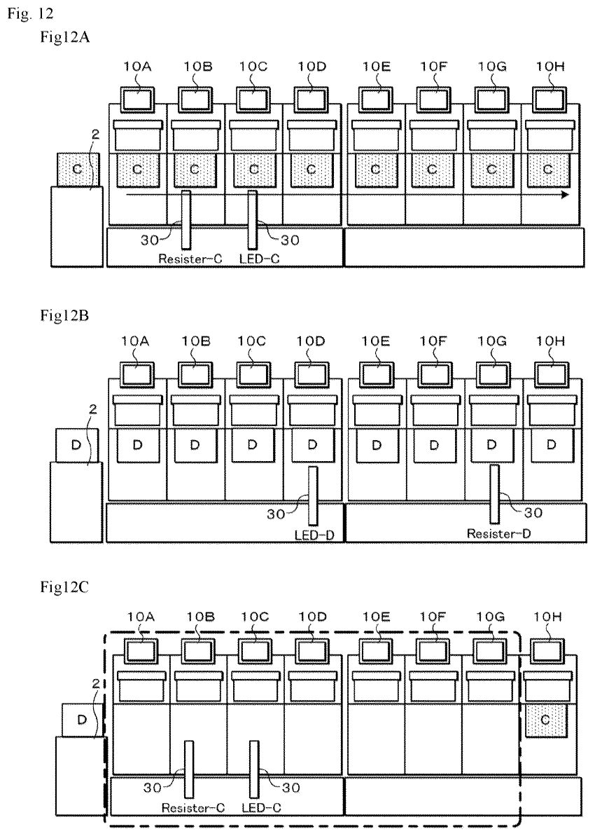

FIGS. 12A to 12C are views illustrating a state in which component mounting machine 10 that performs batch job switching and component mounting machine 10 that performs seamless job switching are determined. As illustrated in FIGS. 12A to 12C, the batch job switching mode is set from most upstream component mounting machine 10A to most downstream component mounting machine 10G among component mounting machines 10B and 10C in which specific combination components used in the current production are set and component mounting machines 10D and 10G in which specific combination components used in the next production are set. As described above, by setting the range of the batch job switching mode as necessary, it is possible to efficiently perform job switching by switching the remaining jobs in the seamless job switching mode while appropriately performing the job switching of component mounting machine 10 including the specific combination components.

Here, a correspondence relationship between the elements of the present embodiment and the elements of the present disclosure will be clarified. Component mounting machines 10A, 10B, 10C, 10D, 10E, 10F, 10G, and 10H of the present embodiment correspond to multiple mounting machines of the present disclosure, the batch job switching mode corresponds to the first job switching, and the seamless job switching mode corresponds to the second job switching.

The present disclosure is not limited in any way to the embodiments described above, and it is needless to say that the present disclosure can be implemented in various forms as long as they belong to the technical scope of the present disclosure.

For example, in the above-described embodiment, in the batch job switching mode, in all component mounting machines 10 in which the batch job switching mode is set, when the mounting of components on last board S for the current production is completed and the setup change is completed, the production of board S for the next production is started. However, when at least specific combination components are set on component mounting machine 10 to be set, the production of board S of the next production may be started as soon as the setup change is completed in order from most upstream component mounting machine 10A.

Further, in the above-described embodiment, CPU 51 sets the job switching mode to the batch job switching mode, from most upstream component mounting machine 10A to component mounting machine 10 in which the specific combination components are set as the components to be mounted in the current production or the next production, and sets the job switching mode of remaining component mounting machines 10 to seamless job switching mode. However, CPU 51 may set either the batch job switching mode or the seamless job switching mode for each component mounting machine 10 based on another condition. In addition, the operator may select the job switching mode to be set for each component mounting machine 10.

In addition, in the above-described embodiment, in the setup change, the operator sets the component (feeder 30) to be mounted on board S for each component mounting machine 10, but some components may be set on each component mounting machine 10 using the automatic conveyance device.

As described above, the first job switching is performed for the first mounting machine group from the most upstream mounting machine to the predetermined downstream mounting machine among the multiple mounting machines constituting the mounting line, and the second job switching is performed for the second mounting machine group located downstream from the predetermined mounting machine. In the first job switching, jobs are switched so that production of the board of the second type is started after the mounting of components on the board of the first type is completed in all the mounting machines in the first mounting machine group and the setup change is completed at least in a specific mounting machine in the first mounting machine group. Meanwhile, in the second job switching, jobs are switched so that the production of the board of the second type is started after a setup change is executed in an upstream mounting machine in the second mounting machine group on which the mounting of components on the board of the first type is completed, in parallel with the mounting of components on the board of the first type by a downstream mounting machine in the second mounting machine group, and the setup change is completed. Accordingly, even when the second job switching cannot be applied to all the mounting machines constituting the mounting line, it is possible to switch jobs more efficiently than when the first job switching is applied to all the mounting machines constituting the mounting line by applying the second job switching to some of the mounting machine.

In the job switching method according to the present disclosure, components to be mounted on the board of the first type or the board of the second type, respectively, may include specific combination components, and the predetermined mounting machine may be a mounting machine located at a most downstream position among multiple mounting machines that respectively mount the combination components. In this way, even when a first component among the specific combination components is not set on the mounting machine and a second component is not determined, the job switching can be appropriately performed by the first job switching. Further, by applying the second job switching to the mounting machine located downstream from the predetermined mounting machine, it is possible to efficiently switch jobs. In this case, in the first job switching, jobs may be switched so that production of the board of the second type is started after mounting of components on the board of the first type is completed in all mounting machines in the first mounting machine group and a setup change is completed in the multiple mounting machines that respectively mount the combination components of the first mounting machine group at least as the specific mounting machine. Further, in this case, both components to be mounted on the board of the first type and components to be mounted on the board of the second type may include the combination components, and the predetermined mounting machine may be a mounting machine located at a most downstream position among multiple mounting machines that mount the combination components on the board of the first type and multiple mounting machines that mount the combination components on the board of the second type. Even when specific combination components are included in both components to be mounted on the board of the first type and components to be mounted on the board of the second type, it is possible to appropriately perform the job switching by the first job switching. Further, in this case, in a setup change of the combination components, when the first component among the combination components is set on a first mounting machine among the multiple mounting machines that mount the combination components, a type of the second component to be set on a second mounting machine may be guided. This facilitates the setup change of the combination components.

The present disclosure is not limited to the form of the job switching method, and may be a form of a mounting line in which multiple mounting machines are arranged in the board conveyance direction.

### INDUSTRIAL APPLICABILITY

The present disclosure can be applied to the manufacturing industry of mounting lines and the like.

### REFERENCE SIGNS LIST

1: component mounting line, 2: board supply device, 10, 10A, 10B, 10C, 10D, 10E, 10F, 10G, 10H: component mounting machine, 21: board conveyance device, 21a: conveyor belt, 22: head, 23: head moving device, 25: mark camera, 26: parts camera, 27: nozzle stocker, 30: feeder, 40: control device, 41: CPU, 42: ROM, 43: RAM, 44: storage device, 50: management device, 51: CPU, 52: ROM, 53: RAM, 54: storage device, 55: input device, 56: display device, 60: reader, S: board

1. A job switching method in a mounting line in which multiple mounting machines configured to mount components on a board are arranged in a conveyance direction of the board, the method comprising:
when switching from a job producing a board of a first type to a job producing a board of a second type, performing, for a first mounting machine group from a most upstream mounting machine to a predetermined downstream mounting machine among multiple mounting machines constituting the mounting line, first job switching of switching jobs so that production of the board of the second type is started after mounting of components on the board of the first type is completed in all mounting machines in the first mounting machine group and a setup change is completed at least in a specific mounting machine in the first mounting machine group, and performing, for a second mounting machine group located downstream of the predetermined mounting machine, second job switching of switching jobs so that the production of the board of the second type is started after a setup change is executed in an upstream mounting machine in the second mounting machine group on which the mounting of components on the board of the first type is completed, in parallel with the mounting of components on the board of the first type by a downstream mounting machine in the second mounting machine group, and the setup change is completed.

2. The job switching method according to claim 1,
wherein components to be mounted on the board of the first type or the board of the second type, respectively, include specific combination components, and
the predetermined mounting machine is a mounting machine located at a most downstream position among multiple mounting machines configured to respectively mount the combination components.

3. The job switching method according to claim 2,
wherein in the first job switching, the jobs are switched so that the production of the board of the second type is started after mounting of components on the board of the first type is completed in all mounting machines in the first mounting machine group and a setup change is completed in the multiple mounting machines that respectively mount the combination components of the first mounting machine group at least as the specific mounting machine.

4. The job switching method according to claim 2,
wherein both components to be mounted on the board of the first type and components to be mounted on the board of the second type include the combination components, and
the predetermined mounting machine is a mounting machine located at a most downstream position among multiple mounting machines configured to mount the combination components on the board of the first type and multiple mounting machines configured to mount the combination components on the board of the second type.

5. The job switching method according to claim 2,
wherein in a setup change of the combination components, when a first component among the combination components is set on a first mounting machine among the multiple mounting machines configured to mount the combination components, a type of a second component to be set on a second mounting machine is guided.

6. A mounting line in which multiple mounting machines configured to mount components on a board are arranged in a conveyance direction of the board,
wherein, when switching from a job producing a board of a first type to a job producing a board of a second type, performing, for a first mounting machine group from a most upstream mounting machine to a predetermined downstream mounting machine among multiple mounting machines constituting the mounting line, first job switching of switching jobs so that production of the board of the second type is started after mounting of components on the board of the first type is completed in all mounting machines in the first mounting machine group and a setup change is completed at least in a specific mounting machine in the first mounting machine group, and performing, for a second mounting machine group located downstream of the predetermined mounting machine, second job switching of switching jobs so that the production of the board of the second type is started after a setup change is executed in an upstream mounting machine in the second mounting machine group on which the mounting of components on the board of the first type is completed, in parallel with the mounting of components on the board of the first type by a downstream mounting machine in the second mounting machine group, and the setup change is completed.
